(19) United States
(12) Patent Application Publication
(10) Pub. No.: US 2025/0212522 A1
(43) Pub. Date: Jun. 26, 2025

(54) CAPPING NANORIBBON FINS IN SUPERLATTICE STRUCTURES DURING FABRICATION

(71) Applicant: Intel Corporation, Santa Clara, CA (US)

(72) Inventors: Cheng-Ying Huang, Vancouver, WA (US); Munzarin F. Qayyum, Hillsboro, OR (US); Kelsey Leigh Jorgensen, Beaverton, OR (US); Clifford John Engel, Hillsboro, OR (US); Jami A. Wiedemer, Scappoose, OR (US); Marko Radosavljevic, Portland, OR (US); Gilbert Dewey, Beaverton, OR (US)

(73) Assignee: Intel Corporation, Santa Clara, CA (US)

(21) Appl. No.: 18/396,584

(22) Filed: Dec. 26, 2023

(51) Int. Cl. H01L 27/12; H01L 21/822; H01L 21/84; H01L 29/423; H01L 29/775; H01L 29/786

(52) U.S. Cl. CPC H10D 87/00; H10D 30/43; H10D 30/6757; H10D 86/01; H10D 30/6735; H10D 84/038; H10D 88/01

(57) ABSTRACT

In embodiments herein, a cap layer (e.g., a layer comprising Silicon) is deposited on a fin formed in a superlattice structure, e.g., during a fabrication process.

### BACKGROUND

As transistor devices become smaller, nanosheet and nanoribbon devices have become the leading type of device architecture, as they have improved performance per watt as compared with other technologies, e.g., planar and FinFET devices. However, due to their small width relative to their height, the fins may be susceptible to bending or other distortion during the fabrication process.

### BRIEF DESCRIPTION OF THE DRAWINGS

FIG. 1 illustrates an example capped nanoribbon fin of a field effect transistor (FET) device in accordance with embodiments herein.

FIGS. 2A-2G illustrate aspects of an example process of manufacturing a nanoribbon FET device in accordance with embodiments herein.

FIGS. 3A-3C illustrate aspects of an example process of manufacturing a nanoribbon FET device with an intermediate oxide layer in accordance with embodiments herein.

FIG. 4 is a top view of a wafer and dies that may be included in a microelectronic assembly, in accordance with any of the embodiments disclosed herein.

FIG. 5 is a cross-sectional side view of an integrated circuit device that may be included in a microelectronic assembly, in accordance with any of the embodiments disclosed herein.

FIG. 6 is a cross-sectional side view of an integrated circuit device assembly that may include a microelectronic assembly, in accordance with any of the embodiments disclosed herein.

FIG. 7 is a block diagram of an example electrical device that may include a microelectronic assembly, in accordance with any of the embodiments disclosed herein.

### DETAILED DESCRIPTION

Embodiments of the present disclosure relate to capping nanoribbon fins of a transistor device, e.g., during fabrication. In some cases, the fabrication of nanosheet/nanoribbon transistor devices may use Silicon/Silicon Germanium (Si/SiGe) superlattice deposition (i.e., with alternating layers of Si/SiGe as described below), where the Si layers become the transistor channel regions and the SiGe layers are used a sacrificial material for the nanosheet/nanoribbon release. However, the existence of the SiGe layer in the superlattice fin may be prone to oxidation, leading to the fin wiggling and/or bending during the fabrication process. As the fin aspect ratio grows taller, e.g., with devices comprising more channels, the Si/SiGe superlattices fin can become mechanically unstable.

This issue can be especially problematic as the number of stacked nanoribbons increases or in 3D monolithic stacked transistor devices (e.g., complementary field effect transistor (CFET) devices with stacked PMOS and NMOS nanoribbon devices). In general, fin bending (low frequency) and wiggling (high frequency) is a function of fin pitch and fin aspect ratio (fin height/fin width). As fins become taller and narrower, the fins tend to bend and wiggle. In an extreme case, two neighboring fins can collapse to each other, thus breaking the downstream fabrication process and decreasing yield.

Furthermore, in nanosheet/nanoribbon technologies, SiGe is inserted into Si/SiGe superlattice fins. The SiGe is lattice mismatched to Si layer in the superlattice. As the fin aspect ratio becomes higher, the fins tend to relax due to the formation of defects in the lattice. In addition, the SiGe layers may be prone to oxidation. Once the SiGe layers become oxidized, the lattice becomes distorted. Both lattice mismatch and SiGe oxidation can cause lattice relaxation and result in a higher likelihood of fin bending. While fin bending/wiggling issues can be mitigated through fin etch processes, shallow trench isolation (STI) processes, and/or design rules, currently known mitigation methods might not resolve the issue caused by the presence of SiGe layer as described above.

Aspects of the present disclosure utilize a cap layer (e.g., a Silicon cap layer) to mitigate potential fin bending and wiggling issue in Si/SiGe superlattices. The cap layer can mechanically stabilize the fin structures and also prevent the SiGe layers in the stack from oxidation in the downstream process. The cap layer can be introduced during the fabrication process, e.g., after the fins are formed in the superlattice structure, and then later removed, e.g., before removing the sacrificial SiGe layers. By implementing a cap layer as described herein, one or more advantages may be seen. As one example, use of a cap layer can allow for higher yields and better logic scaling (e.g., fin pitch scaling or gate extension scaling). In addition, use of a cap layer can allow for higher aspect ratio fins in transistor device by reducing the chances of fin deformation during the fabrication process, allowing for better fabrication of devices such as 3D stacked nanoribbon CFET devices.

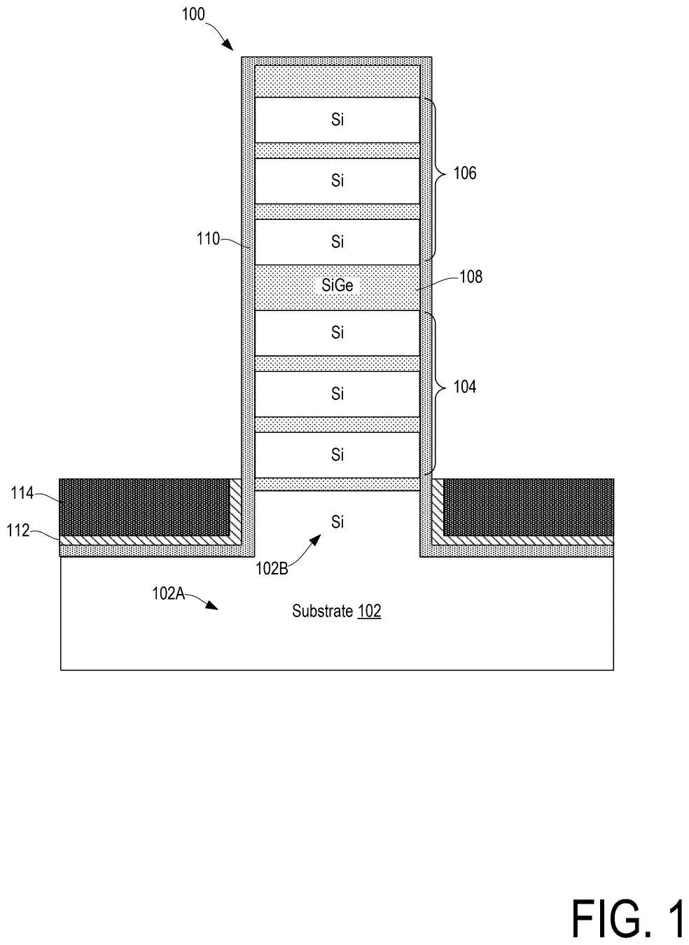

FIG. 1 illustrates an example capped nanoribbon fin 100 of a field effect transistor (FET) device in accordance with embodiments herein. In particular, FIG. 1 illustrates the fin 100 with a cap layer 110 deposited thereon during a fabrication process, e.g., as described further below. The fin 100 is formed on a substrate 102 that includes a body portion 102A and a sub-fin portion 102B (which may be formed during fabrication as described below). The fin 100 is formed from a superlattice structure that includes alternating layers of Silicon and Silicon Germanium as shown. The Silicon layers form a first set of channel regions 104 and a second set of channel regions 106, while the Silicon Germanium layers (e.g., 108) separate the Silicon layers. During fabrication, a cap layer 110 (e.g., a Silicon cap layer) is deposited over the fin 100 such that it covers the top portions of the body portion 102A of the substrate 102, sides of the sub-fin portion 102B of the substrate 102, and the sides and top of the fin 100 as shown. Additional layers 112, 114 may then be deposited for the STI process. The layer 112 may be Silicon Nitride, while the layer 114 may be Silicon Oxide, in certain embodiments.

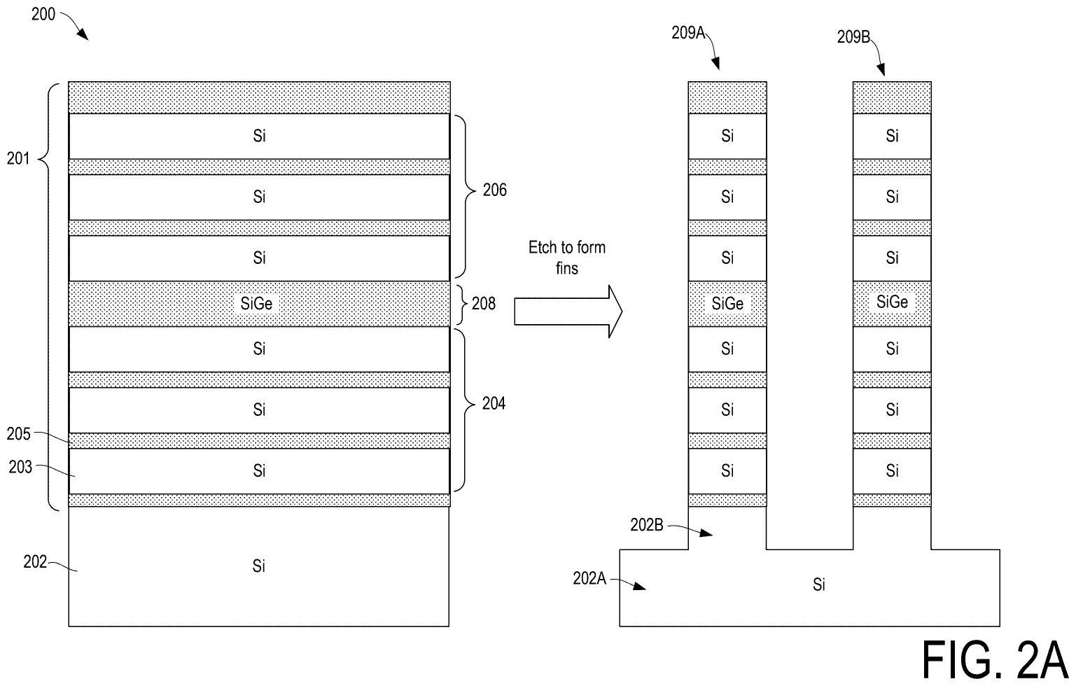

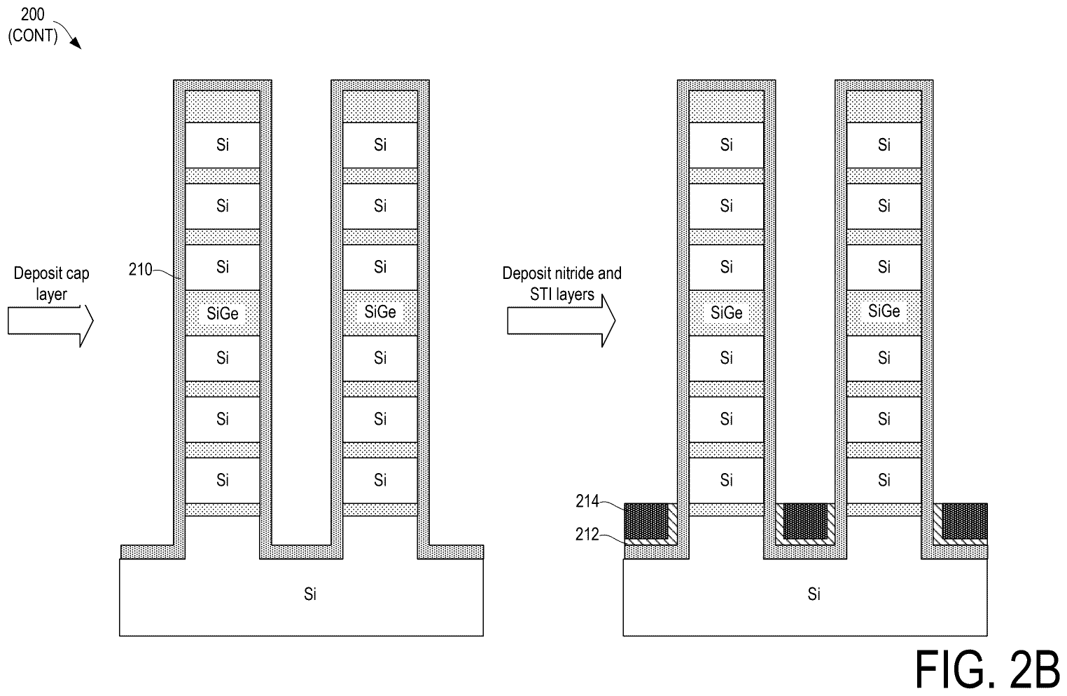

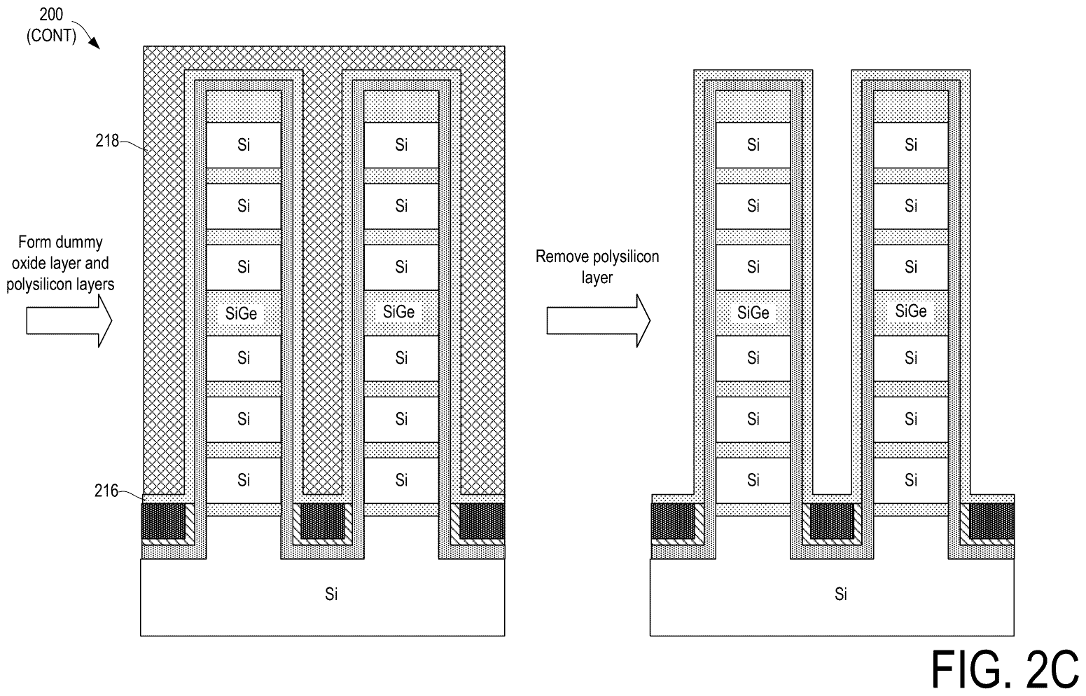

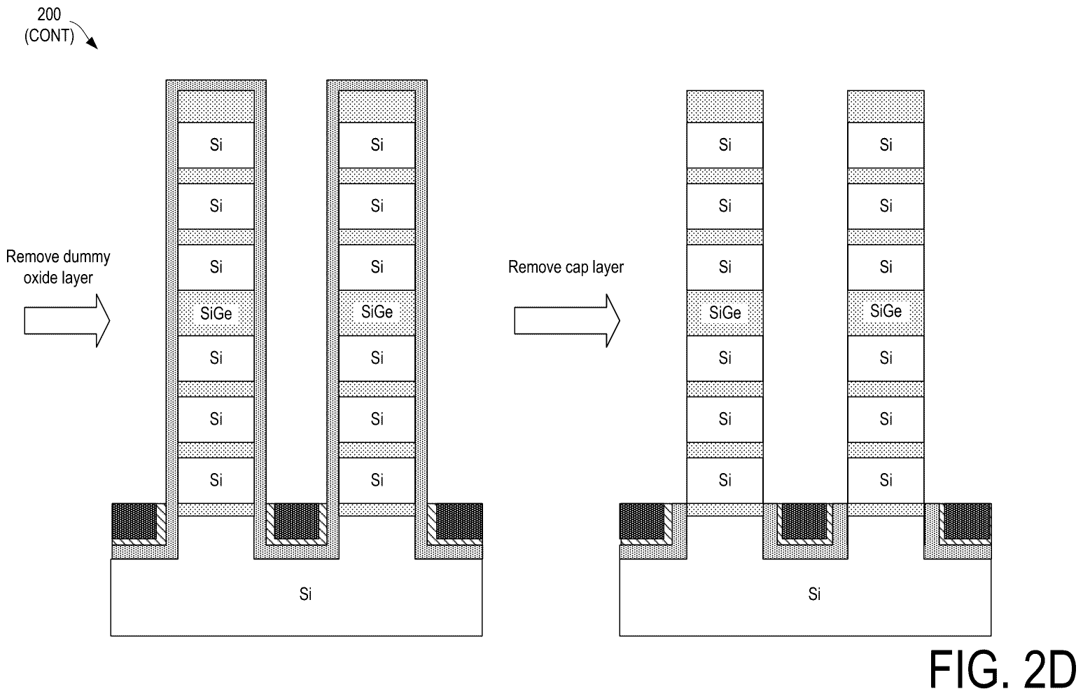

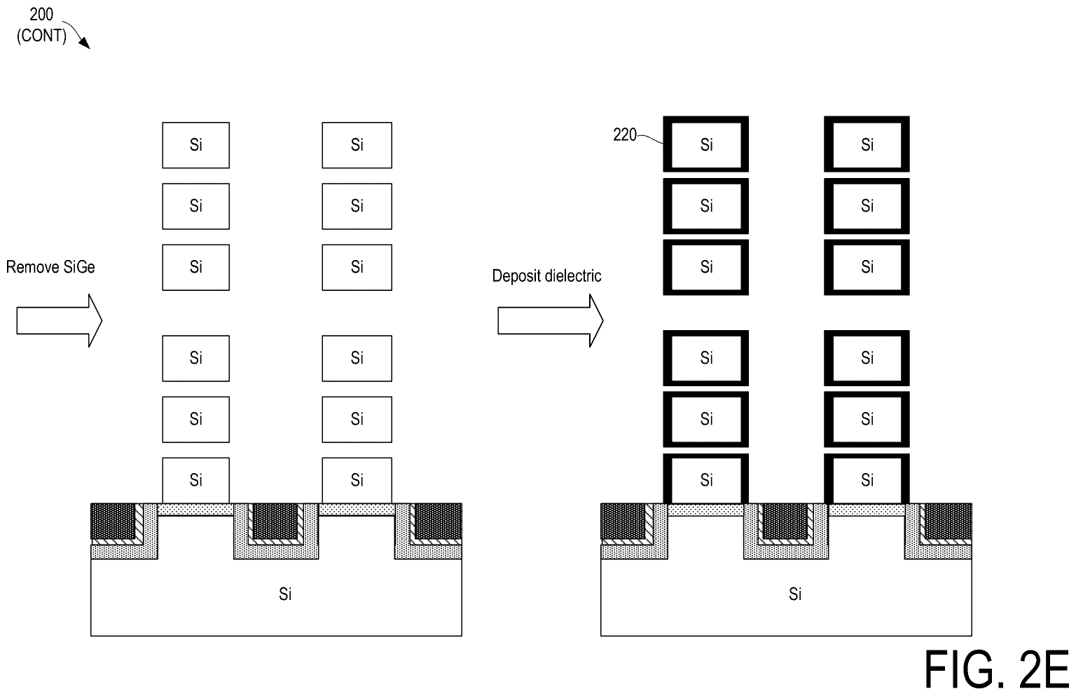

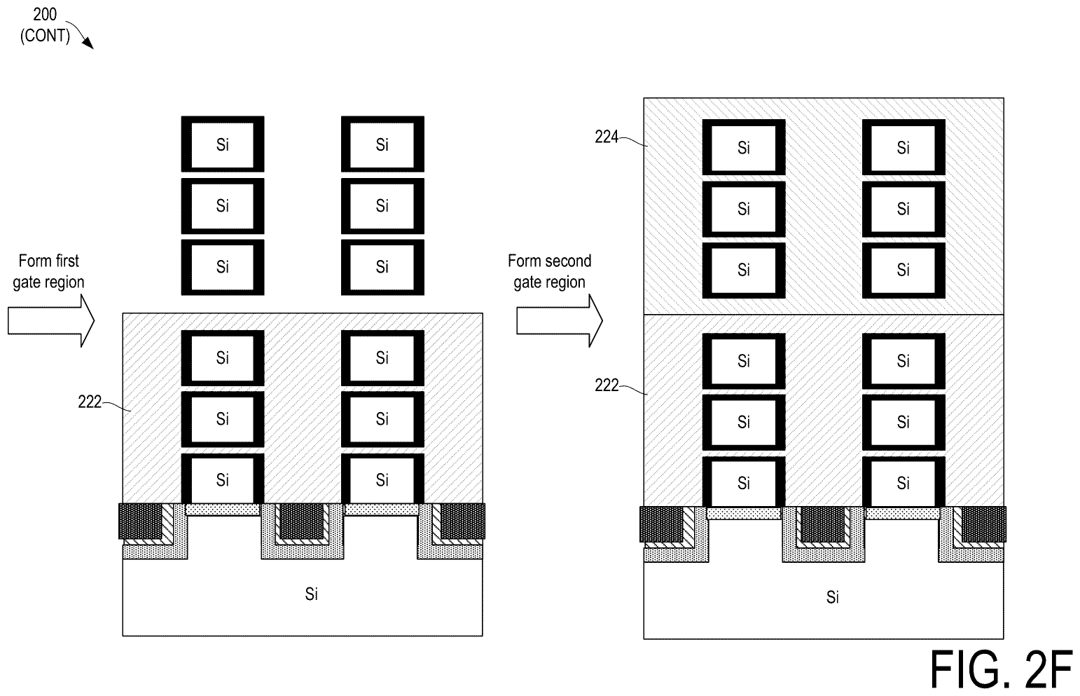

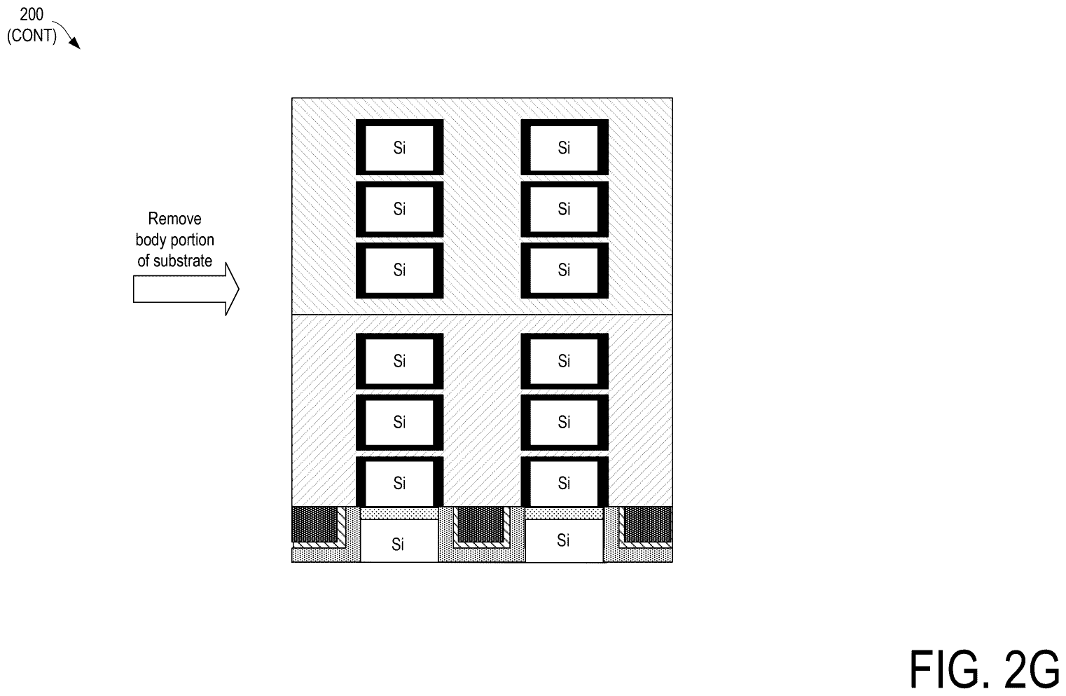

FIGS. 2A-2G illustrate an example process 200 of manufacturing a nanoribbon FET device in accordance with embodiments herein. In particular, the example process 200 shows a simplified flow for depositing a cap layer on fins of a Si/SiGe superlattice. The process 200 may include additional, fewer, or different operations than those shown or described below. In some embodiments, one or more of the operations shown include multiple operations, sub-operations, etc.

FIG. 2A shows a Si/Ge superlattice stack 201 formed on a substrate 202 that includes Silicon. The stack 201 includes alternating layers of Silicon and Silicon Germanium, e.g., 203, 205. The Silicon layers may become the channel regions of the resulting nanoribbon transistor devices, while the SiGe regions may act as sacrificial layer as described below. In some embodiments, the Silicon layers may include dopants. The stack 201 includes a first set of Si channel regions 204 and a second set of Si channel regions 206 with a relatively larger SiGe region 208 (compared with the other SiGe regions of the stack 201, e.g., 205) between the first set 204 and second set 206. Each set 204, 206 includes three channel regions; however, embodiments may include any suitable number of channel regions for a nanoribbon transistor device, including more or less than three. In some instances, the height of each set 204, 206 may be between 30-60 nm (e.g., 45 nm), and the height of the region 208 may be between 20-40 nm (e.g., 30 nm). Although described as being formed with Silicon, the channel regions may be formed from SiGe, Germanium, or a III-V semiconductor material.

Fins 209 are then formed from the stack 201. The fins 209 may be formed by an etching process in certain embodiments, e.g., using photoresist to mask the fin/trench areas. The process may etch into the substrate 202 as shown, causing sub-fin portions 202B to extend from a body portion 202A of the substrate 202 as shown. The fins 209 may each be under 10 nm wide.

Turning to FIG. 2B, a cap layer 210 is deposited on the fins 209, covering the top and sides of the fins 209 (including the sub-fin 202B) and the top surface of the body 202A of the substrate 202. The cap layer 210 may be deposited using the same etching tool used to form the fins 209, e.g., by depositing the layer 210 before exposing the device to air, by atomic layer deposition (ALD), chemical vapor deposition (CVD), furnace-based deposition, or by another suitable type of deposition technique. Then, the device can be put through an STI process, which may include depositing additional layers on the cap layer 210. The layers may include, as shown, a Silicon Nitride (SiNₓ) liner layer 212 and a Silicon Oxide (SiOₓ) layer 214; however, other (e.g., additional) layers may be deposited and/or other materials than SiNₓ or SiOₓ may be used. The layers 212, 214 are then recessed to reveal the fin as shown on the right side of FIG. 2B.

Next, as shown in FIG. 2C, a dummy oxide layer 216 is deposited on the fins and a polysilicon gate layer 218 is formed on the dummy oxide layer 216, e.g., to allow deposition/formation of the source/drain regions of the device (which would be formed on either side of the channel regions 204, 206, into/out of the page). After the source/drain region formation is complete, the layers 216, 218 can be removed along with the cap layer 210 as shown in FIG. 2D. Then, as shown in FIG. 2E, the SiGe layers can be removed from the fins to release the nanoribbon channel regions, allowing for the deposition of the dielectric regions 220 around each of the nanoribbon channel regions as shown. Because the cap layer 210 is removed before the nanoribbon release, the top width of the fin may be smaller than the bottom width of the fin (e.g., the width of the topmost channel region of the fin may be less than the width of the bottommost channel region of the fin). Further, due to the removal of the cap layer 210, the width of each channel region of the fin may be smaller than the width of the sub-fin portion of the substrate.

Gate region(s) can then be formed around the nanoribbon channels and dielectric regions as shown in FIG. 2F. In the example process, two different gate regions 222, 224 are formed. Each region 222, 224 may be formed with the same or different gate material, e.g., metals or conductive oxides. For example, in the case of CFET devices, the gate regions might have different high-k dielectrics or dual metal gates, for example. Although the process 200 illustrates two different gate regions being formed (to create two stacked transistors, e.g., as in a CFET device) one or more gate regions may be formed around the nanoribbon channels, depending on the number of transistor devices being formed from the fin. That is, the process shown can be used for other types of transistor architectures, including 2d nanoribbon architectures. In some embodiments, the body portion of the substrate (or a portion thereof) may be removed in back end processing or otherwise, as shown in FIG. 2G.

In the case of a CFET device, there may also be an insulating layer between the devices of the stack, e.g., between a top device and bottom device of a stacked nanoribbon device as shown in FIGS. 2F, 2G. In addition, some embodiments may also implement a dielectric layer between the bottom SiGe layer and the substrate to isolate the bottom device from the sub-fins.

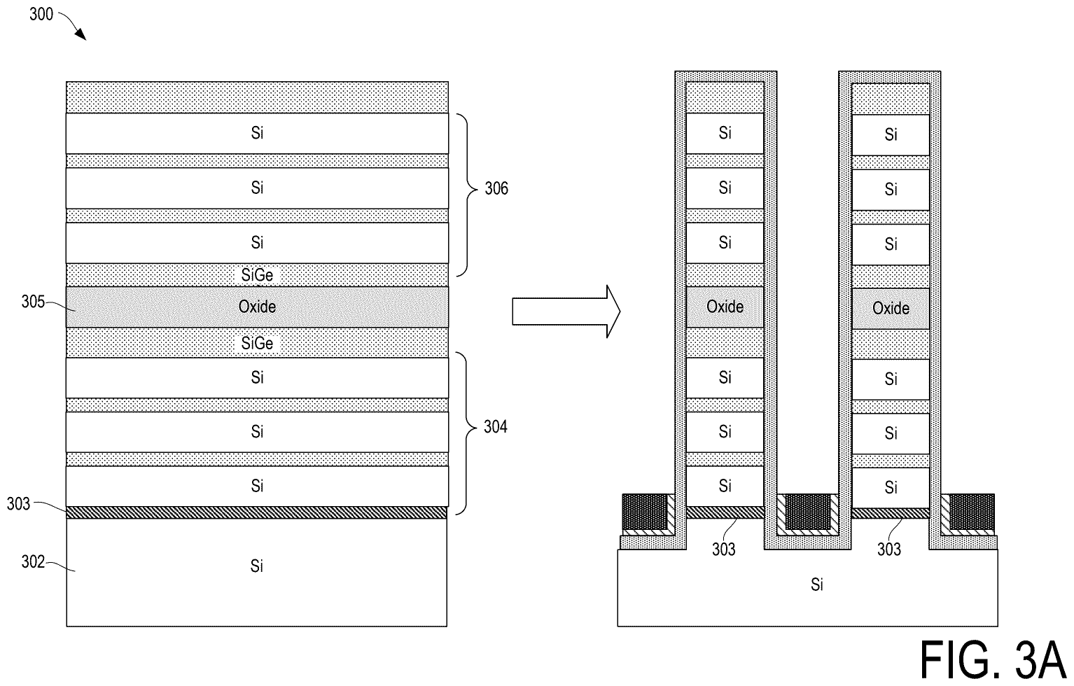

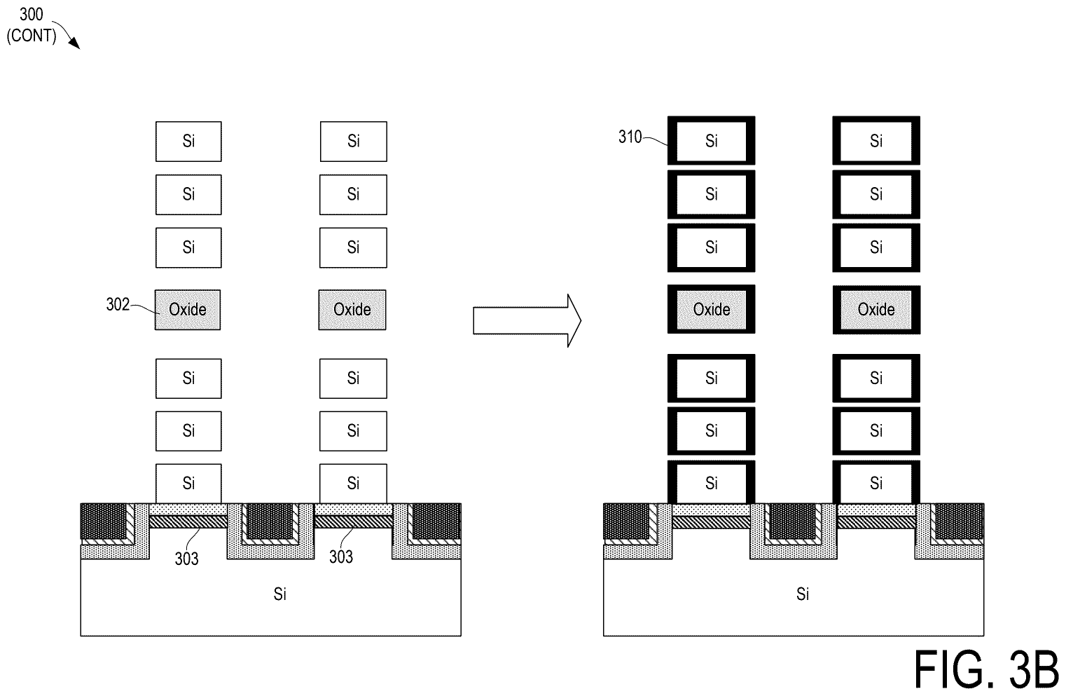

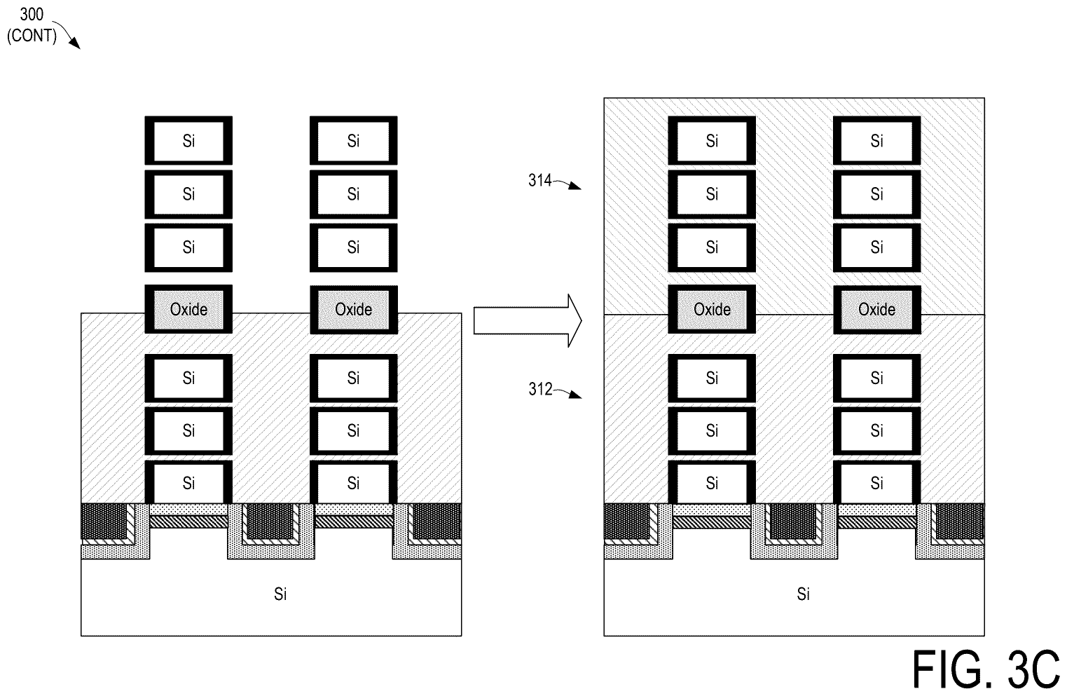

FIGS. 3A-3C illustrate aspects of an example process 300 of manufacturing a nanoribbon FET device with an intermediate oxide layer in accordance with embodiments. herein. The process 300 is effectively the same as the process 200, with fewer operations shown, and being applied to a stack that includes an intermediate isolation layer 305 between the sets 304, 306 of channel regions (for first and second devices 312, 314) and with a dielectric layer 303 between the substrate body 302 and the bottom of the superlattice stack. The example process shown may include additional, fewer, or different operations than those shown or described below, including, e.g., one or more of the operations shown in FIGS. 2A-2G, such as depositing the dielectric layers 310 around the channel regions and the isolation layer 305 as shown in FIG. 3B. In some embodiments, one or more of the operations shown include multiple operations, sub-operations, etc.

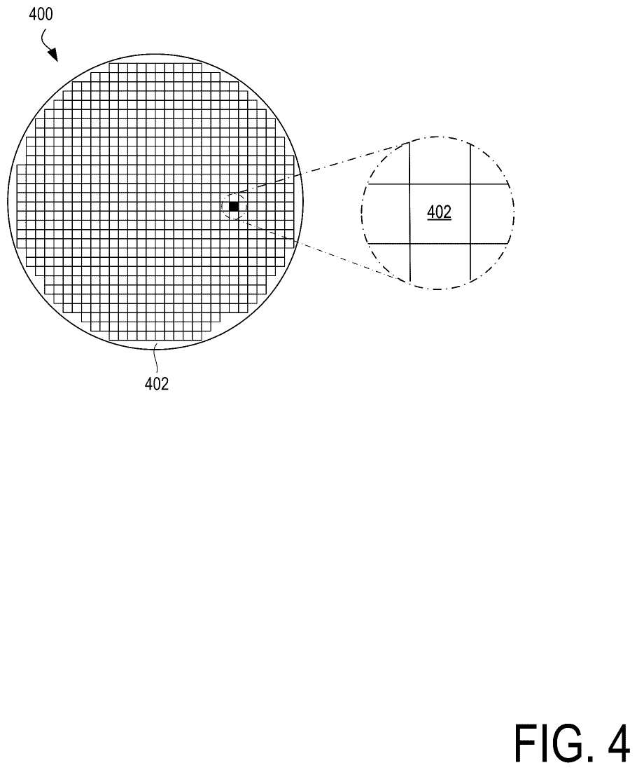

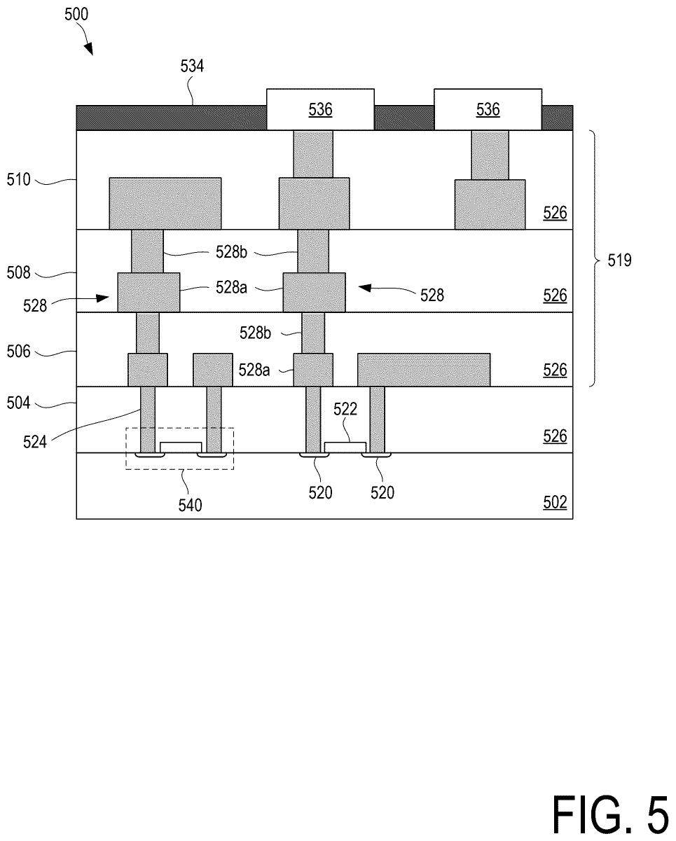

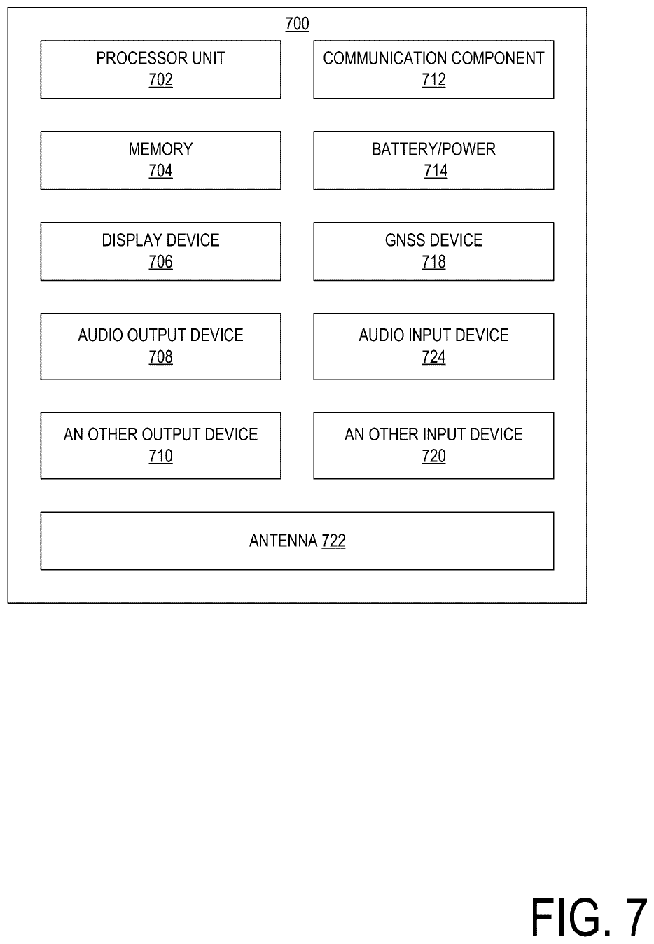

FIG. 4 is a top view of a wafer 400 and dies 402 that may incorporate any of the embodiments disclosed herein. The wafer 400 may be composed of semiconductor material and may include one or more dies 402 having integrated circuit structures formed on a surface of the wafer 400. The individual dies 402 may be a repeating unit of an integrated circuit product that includes any suitable integrated circuit. After the fabrication of the semiconductor product is complete, the wafer 400 may undergo a singulation process in which the dies 402 are separated from one another to provide discrete “chips” of the integrated circuit product. The die 402 may include one or more transistors (e.g., some of the transistors 540 of FIG. 5, discussed below), supporting circuitry to route electrical signals to the transistors, passive components (e.g., signal traces, resistors, capacitors, or inductors), and/or any other integrated circuit components. In some embodiments, the wafer 400 or the die 402 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 402. For example, a memory array formed by multiple memory devices may be formed on a same die 402 as a processor unit (e.g., the processor unit 702 of FIG. 7) or other logic that is configured to store information in the memory devices or execute instructions stored in the memory array.

FIG. 5 is a cross-sectional side view of an integrated circuit device 500 that may be included in any of the embodiments disclosed herein. One or more of the integrated circuit devices 500 may be included in one or more dies 402 (FIG. 4). The integrated circuit device 500 may be formed on a die substrate 502 (e.g., the wafer 400 of FIG. 4) and may be included in a die (e.g., the die 402 of FIG. 4). The die substrate 502 may be a semiconductor substrate composed of semiconductor material systems including, for example, n-type or p-type materials systems (or a combination of both). The die substrate 502 may include, for example, a crystalline substrate formed using a bulk silicon or a silicon-on-insulator (SOI) substructure. In some embodiments, the die substrate 502 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 502. Although a few examples of materials from which the die substrate 502 may be formed are described here, any material that may serve as a foundation for an integrated circuit device 500 may be used. The die substrate 502 may be part of a singulated die (e.g., the dies 402 of FIG. 4) or a wafer (e.g., the wafer 400 of FIG. 4).

The integrated circuit device 500 may include one or more device layers 504 disposed on the die substrate 502. The device layer 504 may include features of one or more transistors 540 (e.g., metal oxide semiconductor field-effect transistors (MOSFETs) or ferroelectric field-effect transistors (FeFETs), e.g., those described herein) formed on the die substrate 502. The transistors 540 may include, for example, one or more source and/or drain (S/D) regions 520, a gate 522 to control current flow between the S/D regions 520, and one or more S/D contacts 524 to route electrical signals to/from the S/D regions 520. The transistors 540 may include additional features not depicted for the sake of clarity, such as device isolation regions, gate contacts, and the like. The transistors 540 are not limited to the type and configuration depicted in FIG. 5 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 5, the example transistor 540 may include a gate 522 formed of at least two layers, a gate dielectric and a gate electrode. The gate dielectric may include one layer or a stack of layers. The one or more layers may include silicon oxide, silicon dioxide, silicon carbide, and/or a high-k dielectric material. However, in other embodiments, the transistors 540 may be FETs that are formed as described in detail above.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 540 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 540 along the source-channel-drain direction, the gate electrode may consist of a U-shaped structure that includes a bottom portion substantially parallel to the surface of the die substrate 502 and two sidewall portions that are substantially perpendicular to the top surface of the die substrate 502. In other embodiments, at least one of the metal layers that form the gate electrode may simply be a planar layer that is substantially parallel to the top surface of the die substrate 502 and does not include sidewall portions substantially perpendicular to the top surface of the die substrate 502. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 520 may be formed within the die substrate 502 adjacent to the gate 522 of individual transistors 540. The S/D regions 520 may be formed using an implantation/diffusion process or an etching/deposition process, for example. In the former process, dopants such as boron, aluminum, antimony, phosphorous, or arsenic may be ion-implanted into the die substrate 502 to form the S/D regions 520. An annealing process that activates the dopants and causes them to diffuse farther into the die substrate 502 may follow the ion-implantation process. In the latter process, the die substrate 502 may first be etched to form recesses at the locations of the S/D regions 520. An epitaxial deposition process may then be carried out to fill the recesses with material that is used to fabricate the S/D regions 520. In some implementations, the S/D regions 520 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 520 may be formed using one or more alternate semiconductor materials such as germanium or a group III-V material or alloy. In further embodiments, one or more layers of metal and/or metal alloys may be used to form the S/D regions 520.

Electrical signals, such as power and/or input/output (I/O) signals, may be routed to and/or from the devices (e.g., transistors 540) of the device layer 504 through one or more interconnect layers disposed on the device layer 504 (illustrated in FIG. 5 as interconnect layers 506-510). For example, electrically conductive features of the device layer 504 (e.g., the gate 522 and the S/D contacts 524) may be electrically coupled with the interconnect structures 528 of the interconnect layers 506-510. The one or more interconnect layers 506-510 may form a metallization stack (also referred to as an “ILD stack”) 519 of the integrated circuit device 500.

The interconnect structures 528 may be arranged within the interconnect layers 506-510 to route electrical signals according to a wide variety of designs; in particular, the arrangement is not limited to the particular configuration of interconnect structures 528 depicted in FIG. 5. Although a particular number of interconnect layers 506-510 is depicted in FIG. 5, embodiments of the present disclosure include integrated circuit devices having more or fewer interconnect layers than depicted.

In some embodiments, the interconnect structures 528 may include lines 528a and/or vias 528b filled with an electrically conductive material such as a metal. The lines 528a may be arranged to route electrical signals in a direction of a plane that is substantially parallel with a surface of the die substrate 502 upon which the device layer 504 is formed. For example, the lines 528a may route electrical signals in a direction in and out of the page and/or in a direction across the page from the perspective of FIG. 5. The vias 528b may be arranged to route electrical signals in a direction of a plane that is substantially perpendicular to the surface of the die substrate 502 upon which the device layer 504 is formed. In some embodiments, the vias 528b may electrically couple lines 528a of different interconnect layers 506-510 together.

The interconnect layers 506-510 may include a dielectric material 526 disposed between the interconnect structures 528, as shown in FIG. 5. In some embodiments, dielectric material 526 disposed between the interconnect structures 528 in different ones of the interconnect layers 506-510 may have different compositions; in other embodiments, the composition of the dielectric material 526 between different interconnect layers 506-510 may be the same. The device layer 504 may include a dielectric material 526 disposed between the transistors 540 and a bottom layer of the metallization stack as well. The dielectric material 526 included in the device layer 504 may have a different composition than the dielectric material 526 included in the interconnect layers 506-510; in other embodiments, the composition of the dielectric material 526 in the device layer 504 may be the same as a dielectric material 526 included in any one of the interconnect layers 506-510.

A first interconnect layer 506 (referred to as Metal 1 or “M1”) may be formed directly on the device layer 504. In some embodiments, the first interconnect layer 506 may include lines 528a and/or vias 528b, as shown. The lines 528a of the first interconnect layer 506 may be coupled with contacts (e.g., the S/D contacts 524) of the device layer 504. The vias 528b of the first interconnect layer 506 may be coupled with the lines 528a of a second interconnect layer 508.

The second interconnect layer 508 (referred to as Metal 2 or “M2”) may be formed directly on the first interconnect layer 506. In some embodiments, the second interconnect layer 508 may include via 528b to couple the lines 528 of the second interconnect layer 508 with the lines 528a of a third interconnect layer 510. Although the lines 528a and the vias 528b are structurally delineated with a line within individual interconnect layers for the sake of clarity, the lines 528a and the vias 528b may be structurally and/or materially contiguous (e.g., simultaneously filled during a dual-damascene process) in some embodiments.

The third interconnect layer 510 (referred to as Metal 3 or “M3”) (and additional interconnect layers, as desired) may be formed in succession on the second interconnect layer 508 according to similar techniques and configurations described in connection with the second interconnect layer 508 or the first interconnect layer 506. In some embodiments, the interconnect layers that are “higher up” in the metallization stack 519 in the integrated circuit device 500 (i.e., farther away from the device layer 504) may be thicker that the interconnect layers that are lower in the metallization stack 519, with lines 528a and vias 528b in the higher interconnect layers being thicker than those in the lower interconnect layers.

The integrated circuit device 500 may include a solder resist material 534 (e.g., polyimide or similar material) and one or more conductive contacts 536 formed on the interconnect layers 506-510. In FIG. 5, the conductive contacts 536 are illustrated as taking the form of bond pads. The conductive contacts 536 may be electrically coupled with the interconnect structures 528 and configured to route the electrical signals of the transistor(s) 540 to external devices. For example, solder bonds may be formed on the one or more conductive contacts 536 to mechanically and/or electrically couple an integrated circuit die including the integrated circuit device 500 with another component (e.g., a printed circuit board). The integrated circuit device 500 may include additional or alternate structures to route the electrical signals from the interconnect layers 506-510; for example, the conductive contacts 536 may include other analogous features (e.g., posts) that route the electrical signals to external components.

In some embodiments in which the integrated circuit device 500 is a double-sided die, the integrated circuit device 500 may include another metallization stack (not shown) on the opposite side of the device layer(s) 504. This metallization stack may include multiple interconnect layers as discussed above with reference to the interconnect layers 506-510, to provide conductive pathways (e.g., including conductive lines and vias) between the device layer(s) 504 and additional conductive contacts (not shown) on the opposite side of the integrated circuit device 500 from the conductive contacts 536.

In other embodiments in which the integrated circuit device 500 is a double-sided die, the integrated circuit device 500 may include one or more through silicon vias (TSVs) through the die substrate 502; these TSVs may make contact with the device layer(s) 504, and may provide conductive pathways between the device layer(s) 504 and additional conductive contacts (not shown) on the opposite side of the integrated circuit device 500 from the conductive contacts 536. In some embodiments, TSVs extending through the substrate can be used for routing power and ground signals from conductive contacts on the opposite side of the integrated circuit device 500 from the conductive contacts 536 to the transistors 540 and any other components integrated into the die 500, and the metallization stack 519 can be used to route I/O signals from the conductive contacts 536 to transistors 540 and any other components integrated into the die 500.

Multiple integrated circuit devices 500 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

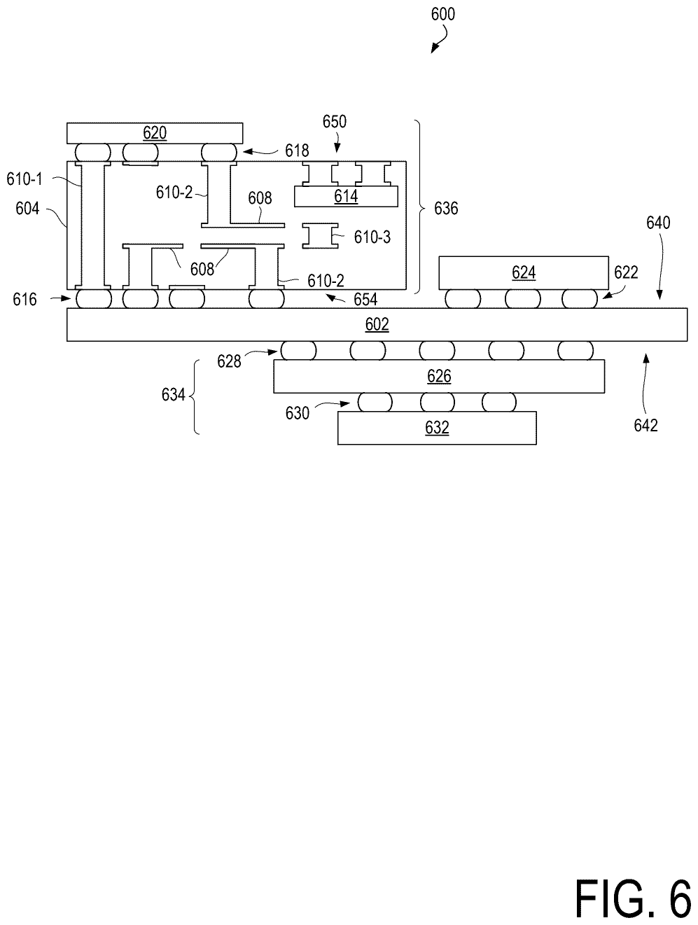

FIG. 6 is a cross-sectional side view of an integrated circuit device assembly 600 that may include any of the embodiments disclosed herein. The integrated circuit device assembly 600 includes a number of components disposed on a circuit board 602 (which may be a motherboard, system board, mainboard, etc.). The integrated circuit device assembly 600 includes components disposed on a first face 640 of the circuit board 602 and an opposing second face 642 of the circuit board 602; generally, components may be disposed on one or both faces 640 and 642.

In some embodiments, the circuit board 602 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 602. In other embodiments, the circuit board 602 may be a non-PCB substrate. The integrated circuit device assembly 600 illustrated in FIG. 6 includes a package-on-interposer structure 636 coupled to the first face 640 of the circuit board 602 by coupling components 616. The coupling components 616 may electrically and mechanically couple the package-on-interposer structure 636 to the circuit board 602, and may include solder balls (as shown in FIG. 6), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 636 may include an integrated circuit component 620 coupled to an interposer 604 by coupling components 618. The coupling components 618 may take any suitable form for the application, such as the forms discussed above with reference to the coupling components 616. Although a single integrated circuit component 620 is shown in FIG. 6, multiple integrated circuit components may be coupled to the interposer 604; indeed, additional interposers may be coupled to the interposer 604. The interposer 604 may provide an intervening substrate used to bridge the circuit board 602 and the integrated circuit component 620.

The integrated circuit component 620 may be a packaged or unpacked integrated circuit product that includes one or more integrated circuit dies (e.g., the die 402 of FIG. 4, the integrated circuit device 500 of FIG. 5) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 620, a single monolithic integrated circuit die comprises solder bumps attached to contacts on the die. The solder bumps allow the die to be directly attached to the interposer 604. The integrated circuit component 620 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 620 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 620 comprises multiple integrated circuit dies, they dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 620 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 604 may spread connections to a wider pitch or reroute a connection to a different connection. For example, the interposer 604 may couple the integrated circuit component 620 to a set of ball grid array (BGA) conductive contacts of the coupling components 616 for coupling to the circuit board 602. In the embodiment illustrated in FIG. 6, the integrated circuit component 620 and the circuit board 602 are attached to opposing sides of the interposer 604; in other embodiments, the integrated circuit component 620 and the circuit board 602 may be attached to a same side of the interposer 604. In some embodiments, three or more components may be interconnected by way of the interposer 604.

In some embodiments, the interposer 604 may be formed as a PCB, including multiple metal layers separated from one another by layers of dielectric material and interconnected by electrically conductive vias. In some embodiments, the interposer 604 may be formed of an epoxy resin, a fiberglass-reinforced epoxy resin, an epoxy resin with inorganic fillers, a ceramic material, or a polymer material such as polyimide. In some embodiments, the interposer 604 may be formed of alternate rigid or flexible materials that may include the same materials described above for use in a semiconductor substrate, such as silicon, germanium, and other group III-V and group IV materials. The interposer 604 may include metal interconnects 608 and vias 610, including but not limited to through hole vias 610-1 (that extend from a first face 650 of the interposer 604 to a second face 654 of the interposer 604), blind vias 610-2 (that extend from the first or second faces 650 or 654 of the interposer 604 to an internal metal layer), and buried vias 610-3 (that connect internal metal layers).

In some embodiments, the interposer 604 can comprise a silicon interposer. Through silicon vias (TSV) extending through the silicon interposer can connect connections on a first face of a silicon interposer to an opposing second face of the silicon interposer. In some embodiments, an interposer 604 comprising a silicon interposer can further comprise one or more routing layers to route connections on a first face of the interposer 604 to an opposing second face of the interposer 604.

The interposer 604 may further include embedded devices 614, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 604. The package-on-interposer structure 636 may take the form of any of the package-on-interposer structures known in the art. In embodiments where the interposer is a non-printed circuit board

The integrated circuit device assembly 600 may include an integrated circuit component 624 coupled to the first face 640 of the circuit board 602 by coupling components 622. The coupling components 622 may take the form of any of the embodiments discussed above with reference to the coupling components 616, and the integrated circuit component 624 may take the form of any of the embodiments discussed above with reference to the integrated circuit component 620.

The integrated circuit device assembly 600 illustrated in FIG. 6 includes a package-on-package structure 634 coupled to the second face 642 of the circuit board 602 by coupling components 628. The package-on-package structure 634 may include an integrated circuit component 626 and an integrated circuit component 632 coupled together by coupling components 630 such that the integrated circuit component 626 is disposed between the circuit board 602 and the integrated circuit component 632. The coupling components 628 and 630 may take the form of any of the embodiments of the coupling components 616 discussed above, and the integrated circuit components 626 and 632 may take the form of any of the embodiments of the integrated circuit component 620 discussed above. The package-on-package structure 634 may be configured in accordance with any of the package-on-package structures known in the art.

FIG. 7 is a block diagram of an example electrical device 700 that may include one or more of the embodiments disclosed herein. For example, any suitable ones of the components of the electrical device 700 may include one or more of the integrated circuit device assemblies 600, integrated circuit components 620, integrated circuit devices 500, or integrated circuit dies 402 disclosed herein. A number of components are illustrated in FIG. 7 as included in the electrical device 700, but any one or more of these components may be omitted or duplicated, as suitable for the application. In some embodiments, some or all of the components included in the electrical device 700 may be attached to one or more motherboards mainboards, or system boards. In some embodiments, one or more of these components are fabricated onto a single system-on-a-chip (SoC) die.

Additionally, in various embodiments, the electrical device 700 may not include one or more of the components illustrated in FIG. 7, but the electrical device 700 may include interface circuitry for coupling to the one or more components. For example, the electrical device 700 may not include a display device 706, but may include display device interface circuitry (e.g., a connector and driver circuitry) to which a display device 706 may be coupled. In another set of examples, the electrical device 700 may not include an audio input device 724 or an audio output device 708, but may include audio input or output device interface circuitry (e.g., connectors and supporting circuitry) to which an audio input device 724 or audio output device 708 may be coupled.

The electrical device 700 may include one or more processor units 702 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 702 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 700 may include a memory 704, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 704 may include memory that is located on the same integrated circuit die as the processor unit 702. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 700 can comprise one or more processor units 702 that are heterogeneous or asymmetric to another processor unit 702 in the electrical device 700. There can be a variety of differences between the processing units 702 in a system in terms of a spectrum of metrics of merit including architectural, microarchitectural, thermal, power consumption characteristics, and the like. These differences can effectively manifest themselves as asymmetry and heterogeneity among the processor units 702 in the electrical device 700.

In some embodiments, the electrical device 700 may include a communication component 712 (e.g., one or more communication components). For example, the communication component 712 can manage wireless communications for the transfer of data to and from the electrical device 700. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 712 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 712 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 712 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 712 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 712 may operate in accordance with other wireless protocols in other embodiments. The electrical device 700 may include an antenna 722 to facilitate wireless communications and/or to receive other wireless communications (such as AM or FM radio transmissions).

In some embodiments, the communication component 712 may manage wired communications, such as electrical, optical, or any other suitable communication protocols (e.g., IEEE 802.3 Ethernet standards). As noted above, the communication component 712 may include multiple communication components. For instance, a first communication component 712 may be dedicated to shorter-range wireless communications such as Wi-Fi or Bluetooth, and a second communication component 712 may be dedicated to longer-range wireless communications such as global positioning system (GPS), EDGE, GPRS, CDMA, WiMAX, LTE, EV-DO, or others. In some embodiments, a first communication component 712 may be dedicated to wireless communications, and a second communication component 712 may be dedicated to wired communications.

The electrical device 700 may include battery/power circuitry 714. The battery/power circuitry 714 may include one or more energy storage devices (e.g., batteries or capacitors) and/or circuitry for coupling components of the electrical device 700 to an energy source separate from the electrical device 700 (e.g., AC line power).

The electrical device 700 may include a display device 706 (or corresponding interface circuitry, as discussed above). The display device 706 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 700 may include an audio output device 708 (or corresponding interface circuitry, as discussed above). The audio output device 708 may include any embedded or wired or wirelessly connected external device that generates an audible indicator, such speakers, headsets, or earbuds.

The electrical device 700 may include an audio input device 724 (or corresponding interface circuitry, as discussed above). The audio input device 724 may include any embedded or wired or wirelessly connected device that generates a signal representative of a sound, such as microphones, microphone arrays, or digital instruments (e.g., instruments having a musical instrument digital interface (MIDI) output). The electrical device 700 may include a Global Navigation Satellite System (GNSS) device 718 (or corresponding interface circuitry, as discussed above), such as a Global Positioning System (GPS) device. The GNSS device 718 may be in communication with a satellite-based system and may determine a geolocation of the electrical device 700 based on information received from one or more GNSS satellites, as known in the art.

The electrical device 700 may include an other output device 710 (or corresponding interface circuitry, as discussed above). Examples of the other output device 710 may include an audio codec, a video codec, a printer, a wired or wireless transmitter for providing information to other devices, or an additional storage device.

The electrical device 700 may include another input device 720 (or corresponding interface circuitry, as discussed above). Examples of the other input device 720 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 700 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 700 may be any other electronic device that processes data. In some embodiments, the electrical device 700 may comprise multiple discrete physical components. Given the range of devices that the electrical device 700 can be manifested as in various embodiments, in some embodiments, the electrical device 700 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is a transistor device comprising: a substrate defining a sub-fin portion extending upward from a body of the substrate; a layer comprising Silicon on the body portion of the substrate and on sides of the sub-fin portion of the substrate; a plurality of first channel regions above the sub-fin portion of the substrate, each first channel region comprising Silicon; a first gate region surrounding the first channel regions; dielectric regions between each first channel region and the first gate region; a plurality of second channel regions above the first channel regions, each second channel region comprising Silicon; a second gate region surrounding the second channel regions; and dielectric regions between each second channel region and the first gate region.

Example 2 includes the subject matter of Example 1, wherein the layer comprising Silicon is a first layer and the device further comprises a second layer comprising Silicon and Nitrogen on the first layer.

Example 3 includes the subject matter of Example 2, further comprising a third layer comprising Silicon and Oxygen on the second layer.

Example 4 includes the subject matter of any one of Examples 1-3, further comprising an isolation region between the first channel regions and the second channel regions.

Example 5 includes the subject matter of any one of Examples 1-4, further comprising a dielectric layer between the sub-fin portion of the substrate and the first channel regions.

Example 6 includes the subject matter of any one of Examples 1-5, further comprising a layer comprising Silicon and Germanium between the sub-fin portion of the substrate and the first channel regions.

Example 7 includes the subject matter of any one of Examples 1-6, wherein the layer comprising Silicon is 1-4 nm thick.

Example 8 includes the subject matter of any one of Examples 1-7, wherein a width of the channel regions is less than a width of the sub-fin portion of the substrate.

Example 9 includes the subject matter of any one of Examples 1-8, wherein a width of the channel regions is less than 10 nm.

Example 10 includes the subject matter of any one of Examples 1-9, wherein a height of the device is between 100-140 nm.

Example 11 is a transistor device comprising: a sub-fin region comprising Silicon; a layer comprising Silicon on sides of the sub-fin region; a fin region above the sub-fin region, the fin region comprising: channel regions, each channel region comprising Silicon; respective dielectric regions around each channel region; a first gate region around a first subset of the channel regions; and a second gate region around a second subset of the channel regions, the second gate region above the first gate region.

Example 12 includes the subject matter of Example 11, wherein the layer comprising Silicon is a first layer and the device further comprises a second layer comprising Silicon and Nitrogen on the first layer.

Example 13 includes the subject matter of Example 12, further comprising a third layer comprising Silicon and Oxygen on the second layer.

Example 14 includes the subject matter of any one of Examples 11-13, further comprising an isolation region between a first set of channel regions and a second set of channel regions.

Example 15 includes the subject matter of any one of Examples 11-14, further comprising a dielectric layer between the sub-fin region and the channel regions.

Example 16 includes the subject matter of any one of Examples 11-15, further comprising a layer comprising Silicon and Germanium between the sub-fin region and the channel regions.

Example 17 includes the subject matter of any one of Examples 11-16, wherein the layer comprising Silicon is 1-4 nm thick.

Example 18 includes the subject matter of any one of Examples 11-17, wherein a width of the channel regions is less than a width of the sub-fin region.

Example 19 includes the subject matter of any one of Examples 11-18, wherein a width of the channel regions is less than 10 nm.

Example 20 includes the subject matter of any one of Examples 11-19, wherein a height of the device is between 100-140 nm.

Example 21 is an integrated circuit device comprising a plurality of transistor devices, at least one transistor device of the integrated circuit device according to any one of Examples 1-20.

Example 22 is an integrated circuit device assembly comprising a circuit board and an integrated circuit component coupled to the circuit board, the integrated circuit component comprising a package substrate and an integrated circuit device coupled to the package substrate, the integrated circuit device according to Example 21.

Example 22 is a method of manufacturing a transistor device comprising: forming fins in superlattice structure comprising a plurality of alternating first and second layers, the first layers comprising Silicon and the second layers comprising Silicon and Germanium; forming a third layer on the fins, the third layer comprising Silicon; forming a fourth layer on the third layer, the fourth layer comprising Silicon and Oxygen; forming a fifth layer on the fourth layer, the fifth layer comprising Polysilicon; removing the fifth layer, the fourth layer, and a portion of the third layer; removing the second layers of the superlattice structure; depositing a dielectric around remaining first layers; forming a first gate region around a first set of remaining first layers; and forming a second gate region around a second set of remaining first layers.

Example 24 includes the subject matter of Example 23, wherein forming the third layer comprises depositing the third layer using one of an atomic layer deposition (ALD) technique and a chemical vapor deposition (CVD) technique.

Example 25 includes the subject matter of Example 23 or 24, wherein forming the fins in the superlattice structure comprises etching the superlattice structure, and wherein the third layer is formed using the etching tool.

Example 26 is a transistor device comprising: a substrate; a sub-fin extending from the substrate; a layer comprising Silicon on the substrate and on sides of the sub-fin; a plurality of first channel regions above the sub-fin of the substrate, each first channel region comprising Silicon; a first gate region surrounding the first channel regions; dielectric regions between each first channel region and the first gate region; a plurality of second channel regions above the first channel regions, each second channel region comprising Silicon; a second gate region surrounding the second channel regions; and dielectric regions between each second channel region and the first gate region.

Example 27 includes the subject matter of Example 26, wherein the layer comprising Silicon is a first layer and the device further comprises a second layer comprising Silicon and Nitrogen on the first layer.

Example 28 includes the subject matter of Example 27, further comprising a third layer comprising Silicon and Oxygen on the second layer.

Example 29 includes the subject matter of any one of Examples 26-28, further comprising an isolation region between the first channel regions and the second channel regions.

Example 30 includes the subject matter of any one of Examples 26-29, further comprising a dielectric layer between the sub-fin portion of the substrate and the first channel regions.

Example 31 includes the subject matter of any one of Examples 26-30, further comprising a layer comprising Silicon and Germanium between the sub-fin portion of the substrate and the first channel regions.

Example 32 includes the subject matter of any one of Examples 26-31, wherein the layer comprising Silicon is 1-4 nm thick.

Example 33 includes the subject matter of any one of Examples 26-32, wherein a width of the channel regions is less than a width of the sub-fin portion of the substrate.

Example 34 includes the subject matter of any one of Examples 26-33, wherein a width of the channel regions is less than 10 nm.

Example 35 includes the subject matter of any one of Examples 26-34, wherein a height of the device is between 100-140 nm.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

In various embodiments, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

In various embodiments, the term “adjacent” refers to layers or components that are in physical contact with each other. That is, there is no layer or component between the stated adjacent layers or components. For example, a layer X that is adjacent to a layer Y refers to a layer that is in physical contact with layer Y.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. A transistor device comprising:
a substrate;
a sub-fin extending from the substrate;
a layer comprising Silicon on the substrate and on sides of the sub-fin;
a plurality of first channel regions above the sub-fin of the substrate, each first channel region comprising Silicon;
a first gate region surrounding the first channel regions;
dielectric regions between each first channel region and the first gate region;
a plurality of second channel regions above the first channel regions, each second channel region comprising Silicon;
a second gate region surrounding the second channel regions; and
dielectric regions between each second channel region and the first gate region.

2. The device of claim 1, wherein the layer comprising Silicon is a first layer and the device further comprises a second layer comprising Silicon and Nitrogen on the first layer.

3. The device of claim 2, further comprising a third layer comprising Silicon and Oxygen on the second layer.

4. The device of claim 1, further comprising an isolation region between the first channel regions and the second channel regions.

5. The device of claim 1, further comprising a dielectric layer between the sub-fin and the first channel regions.

6. The device of claim 1, further comprising a layer comprising Silicon and Germanium between the sub-fin and the first channel regions.

7. The device of claim 1, wherein the layer comprising Silicon is 1-4 nm thick.

8. The device of claim 1, wherein a width of the channel regions is less than a width of the sub-fin.

9. The device of claim 1, wherein a width of the channel regions is less than 10 nm.

10. The device of claim 1, wherein a height of the device is between 100-140 nm.

11. A transistor device comprising:
a sub-fin region comprising Silicon;
a layer comprising Silicon on sides of the sub-fin region;
a fin region above the sub-fin region, the fin region comprising:
channel regions, each channel region comprising Silicon;
respective dielectric regions around each channel region;
a first gate region around a first subset of the channel regions; and
a second gate region around a second subset of the channel regions, the second gate region above the first gate region.

12. The transistor device of claim 11, wherein the layer comprising Silicon is a first layer and the device further comprises a second layer comprising Silicon and Nitrogen on the first layer.

13. The device of claim 12, further comprising a third layer comprising Silicon and Oxygen on the second layer.

14. The device of claim 11, further comprising an isolation region between a first set of channel regions and a second set of channel regions.

15. The device of claim 11, further comprising a dielectric layer between the sub-fin region and the channel regions.

16. The device of claim 11, further comprising a layer comprising Silicon and Germanium between the sub-fin region and the channel regions.

17. The device of claim 11, wherein the layer comprising Silicon is 1-4 nm thick.

18. The device of claim 11, wherein a width of the channel regions is less than a width of the sub-fin region.

19. A method of manufacturing a transistor device comprising:
forming fins in superlattice structure comprising a plurality of alternating first and second layers, the first layers comprising Silicon and the second layers comprising Silicon and Germanium;
forming a third layer on the fins, the third layer comprising Silicon;
forming a fourth layer on the third layer, the fourth layer comprising Silicon and Oxygen;
forming a fifth layer on the fourth layer, the fifth layer comprising Polysilicon;
removing the fifth layer, the fourth layer, and a portion of the third layer;
removing the second layers of the superlattice structure;
depositing a dielectric around remaining first layers;
forming a first gate region around a first set of remaining first layers; and
forming a second gate region around a second set of remaining first layers.

20. The method of claim 19, wherein forming the third layer comprises depositing the third layer using one of an atomic layer deposition (ALD) technique and a chemical vapor deposition (CVD) technique.
